(19) United States
(12) Patent Application Publication
(10) Pub. No.: US 2026/0278195 A1
(43) Pub. Date: Sep. 17, 2026

(54) SYSTEMS AND METHODS FOR ASSISTING IN PRODUCTION OF COMPONENTS

(71) Applicant: HONEYWELL INTERNATIONAL INC., Charlotte, NC (US)

(72) Inventors: Carl Arthur Dins, Torrance, CA (US); Gregory Colvin, Plymouth, MN (US); Partha Das, Phoenix, AZ (US)

(73) Assignee: HONEYWELL INTERNATIONAL INC., Charlotte, NC (US)

(21) Appl. No.: 19/079,834

(22) Filed: Mar. 14, 2025

(51) Int. Cl. G06F 30/17

(52) U.S. Cl. CPC G06F 30/17

(57) ABSTRACT

Systems and methods are provided that are configured to assist in the production of components. The systems include a producibility predictive model (PPM) and a generative design model (GDM) both executable on one or more processors of the system. The PPM is configured to receive a computer-generated three-dimensional (3D) component model representative of a component to be produced, and determine an estimated producibility of the component based on at least a geometry thereof. The estimated producibility is indicative of a difficultly of manufacturing that the component. The GDM is configured to determine a modification to the component to improve the producibility thereof, and generate a commented 3D component model representative of the component with an aspect thereof marked with a reference to the modification, and/or a modified 3D component model representative of a modified version of the component with an aspect thereof changed based on the modification.

### TECHNICAL FIELD

The present invention generally relates to cast components, and more particularly relates to systems and methods configured to determine a producibility of components based on three-dimensional (3D) component models thereof and generate modifications to the components intended to promote ease of producing the components and potentially reduce cost and/or lead time.

### BACKGROUND

The production process of creating new cast components typically includes a plurality of steps often performed by various individuals. If an issue with the design of a component is identified late in the production process, addressing the issue may require previous steps to be repeated. This can extend the production process life cycle with increased cost and reduce the efficiency of producing new components.

Therefore, there is an ongoing desire for systems and methods that provide additional information to designers early in the production process, and/or that assist in the production of new components. Furthermore, other desirable features and characteristics of the present invention will become apparent from the subsequent detailed description and the appended claims, taken in conjunction with the accompanying drawings and the foregoing technical field and background.

### BRIEF SUMMARY

This summary is provided to describe select concepts in a simplified form that are further described in the Detailed Description. This summary is not intended to identify key or essential features of the claimed subject matter, nor is it intended to be used as an aid in determining the scope of the claimed subject matter.

In various examples, a method is provided that includes receiving a computer-generated three-dimensional (3D) component model representative of a component to be produced, determining, with a producibility predictive model (PPM), an estimated producibility of the component based on at least a geometry thereof as represented in the 3D component model, wherein the estimated producibility is indicative of a difficultly of manufacturing that the component, determining, with a generative design model (GDM), at least one modification to the component configured to improve the producibility of the component, and generating, with the GDM a commented 3D component model representative of the component with one or more aspects thereof marked with a reference to the at least one modification, and/or a modified 3D component model representative of a modified version of the component wherein one or more aspects of the component has been changed based on the at least one modification.

In various examples, a system is provided that includes a producibility predictive model (PPM) and a generative design model (GDM) both executable on one or more processors of the system. The PPM is configured to receive a computer-generated three-dimensional (3D) component model representative of a component to be produced, and determine an estimated producibility of the component based on at least a geometry thereof as represented in the 3D component model, wherein the estimated producibility is indicative of a difficultly of manufacturing the component. The GDM is configured to determine at least one modification to the component configured to improve the producibility of the component, and generate a commented 3D component model representative of the component with one or more aspects thereof marked with a reference to the at least one modification, and/or a modified 3D component model representative of a modified version of the component wherein one or more aspects of the component has been changed based on the at least one modification.

In various examples, a system is provided that includes a producibility predictive model (PPM) and a generative design model (GDM) both executable on one or more processors of the system. The PPM is configured to receive a computer-generated three-dimensional (3D) component model representative of a gas turbine component configured to be produced with a casting process and installed in a gas turbine, and determine an estimated producibility of the component based on at least a geometry thereof as represented in the 3D component model, wherein the estimated producibility is indicative of a difficultly of manufacturing the component. The GDM is configured to determine at least one modification to the component configured to improve the producibility of the component, and generate a commented 3D component model representative of the component with one or more aspects thereof marked with a reference to the at least one modification, and/or a modified 3D component model representative of a modified version of the component wherein one or more aspects of the component has been changed based on the at least one modification. The PPM includes a first 3D-aware machine learning model trained with a dataset of 3D component models and associated production thresholds and/or producibility parameters. The GDM includes a second 3D-aware machine learning model trained on the dataset of 3D component models, wherein the GDM is configured to sample components from the dataset of 3D component models to determine the at least one modification and generate the commented 3D component model and/or the modified 3D component model.

Furthermore, other desirable features and characteristics of the systems and method will become apparent from the subsequent detailed description and the appended claims, taken in conjunction with the accompanying drawings and the preceding background.

### BRIEF DESCRIPTION OF DRAWINGS

The present disclosure will hereinafter be described in conjunction with the following drawing figures, wherein like numerals denote like elements, and wherein:

FIG. 1 represents a system for assisting in the design of cast components in accordance with an embodiment;

FIG. 2 is a dataflow diagram illustrating operation of the system of FIG. 1 in accordance with an embodiment;

FIG. 3 is a flowchart illustrating an exemplary method for assisting in production of a cast component in accordance with an embodiment;

FIG. 4 is a flowchart illustrating an exemplary method for training and/or producing machine learning models for assisting in production of a cast component in accordance with an embodiment.

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

For the sake of brevity, conventional techniques related to signal processing, data transmission, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

Systems and methods disclosed herein provide for assisting in the design of new cast components, particularly components of gas turbine engines. In general, the systems and methods are configured for predicting a producibility of components, and providing recommendations and/or modifications thereto that may improve the producibility thereof. Producibility as used herein refers to a measurement of an ease of manufacturability, that is, how easy it would be to manufacture a component. The system and methods may analyze a component model, such as a design model of a component for a gas turbine engine. The component model may be designed with computer aided design (CAD) software and may include three-dimensional (“3D") numeric coordinates of the entire configuration of the component including both external and internal surfaces. The component may be configured to be or intended to be formed according to the component model using a casting process. The systems and methods may be used to facilitate ease of manufacture, that is, designing components in a way so it is easier to manufacture.

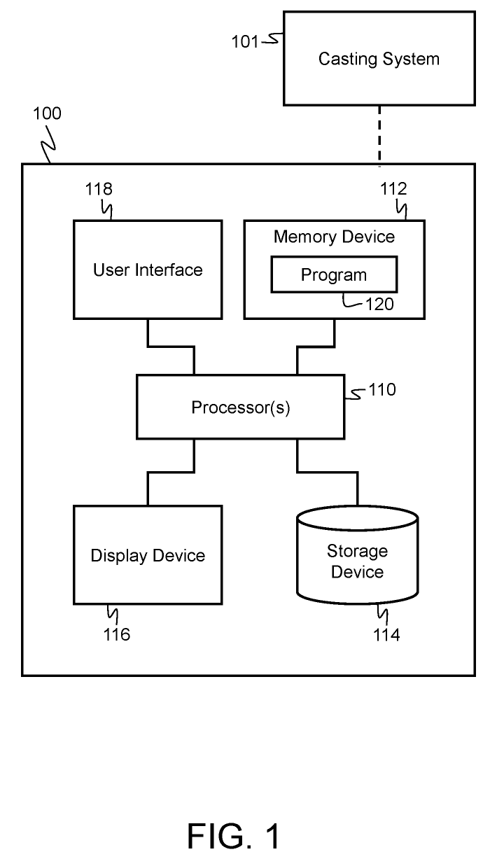

Referring now to FIG. 1, an exemplary system 100 is represented in accordance with an embodiment of the present disclosure. The system 100 includes and/or is functionally coupled to the following components or subsystems, each of which may assume the form of a single device or multiple interconnected devices, including, but not limited to, at least one processor 110 operationally coupled to a computer-readable storage media or memory device 112, a storage device 114, an optional display device 116, and an optional user interface 118. Although schematically illustrated in FIG. 1 as a single unit, the individual elements and components of the system 100 can be implemented in a distributed manner utilizing any practical number of physically distinct and operatively interconnected pieces of hardware or equipment. In some examples, the system 100 may include or be in functional communication with a casting system 101 configured to produce an article using a casting process based on, for example, a 3D component model of the article.

The processor 110 performs the computation and control functions of the system 100. The processor 110 can be any custom made or commercially available processor, a central processing unit (CPU), a graphics processing unit (GPU), an auxiliary processor among several processors associated with therewith, a semiconductor-based microprocessor (in the form of a microchip or chip set), any combination thereof, or generally any device for executing instructions.

The memory device 112 may include volatile and nonvolatile storage in read-only memory (ROM), random-access memory (RAM), and/or any other type of storage media. The memory device 112 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the processor 110.

The instructions may include one or more separate programs, each of which comprises an ordered listing of executable instructions for implementing logical functions. The instructions, when executed by the processor 110, perform logic, calculations, methods and/or algorithms, and generate data based on the logic, calculations, methods, and/or algorithms. In various embodiments, the processor 110 includes or cooperates with at least one firmware and software program (generally, computer-readable instructions that embody an algorithm) for carrying-out the various process tasks, calculations, and control/display functions described herein. During operation, the processor 110 may be programmed with and execute at least one firmware or software program, for example, a program 120, that embodies one or more algorithms, to thereby perform the various process steps, tasks, calculations, and control/display functions described herein.

The storage device 114 may include various type of computer readable storage media configured for storing information suitable for operating the system 100. In certain embodiments, the storage device 114 may be configured to receive and store 3D component models and associated production parameter data and/or producibility parameter data, which may be updated on a periodic or iterative basis to ensure data timeliness. In various embodiments, the stored data may be referenceable by the program 120.

The display device 116 can include any number and type of image generating devices on which one or more displays may be produced, such as one or more monitors, laptop screens, tablet computer screens, or smart phone screens.

The user interface 118 may include various human-machine interface devices such as keyboards, pointers, etc. In some examples, the user interface 118 may include a touch screen display implemented as an integration of the user interface 118 and the display device 116. Via various display and graphics systems processes, the processor 110 may command and control the display device 116 to generate a variety of graphical user interface (GUI) objects or elements, for example, buttons, sliders, and the like, which are used to prompt a user to interact with the user interface 118 to provide user input, and to activate respective functions and provide user feedback, responsive to received user input at the GUI element.

The casting system 101 may include various apparatuses configured to produce an article using a casting process. For example, the casting system 101 may include apparatuses configured to performed an investment casting process including producing a wax pattern of the article, coating the wax pattern with a ceramic slurry to form a ceramic shell, heating the ceramic shell to melt and remove the wax pattern, filling a cavity of the ceramic shell (mold), removing the casting from the ceramic shell, performing inspection processes on the casting, and optionally performing post-casting treatments such as heat treatments, machining, surface finishing, etc.

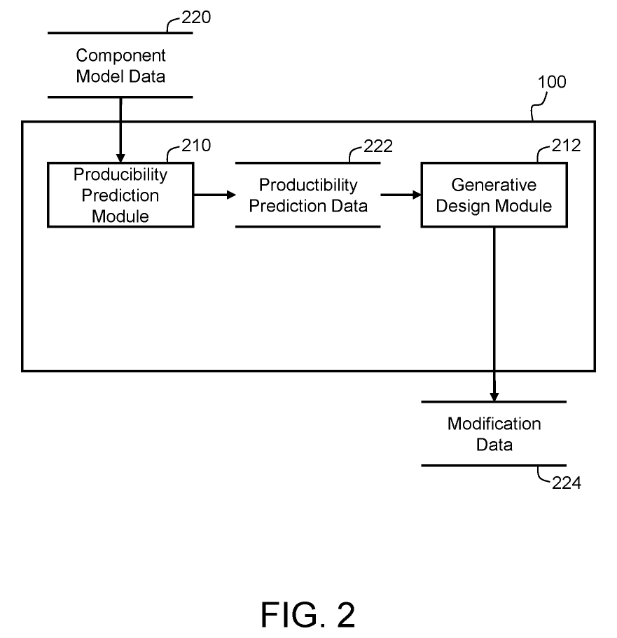

With reference to FIG. 2 and with continued reference to FIG. 1, a dataflow diagram illustrates elements of the system 100 of FIG. 1 in accordance with various embodiments. As can be appreciated, various embodiments of the system 100 according to the present disclosure may include any number of modules embedded within the processor 110 and/or the memory device 112 which may be combined and/or further partitioned to similarly implement systems and methods described herein. In various embodiments, the system 100 includes a producibility prediction module 210, and a generative design module 212.

In various embodiments, the producibility prediction module 210 receives as input component model data 220 that includes various data indicating a geometry of a component intended to be produced via a casting process. In various examples, the component model data 220 may include a 3D component model generated by, for example, a CAD software executed on the system 100 or on another system separate from the system 100. For example, the 3D component model may include data representing the component by a point cloud, a triangle mesh, parametric or geometric shapes, a sequence of triangles, and/or by a series of commands. Optionally, the component model data 220 may be indicative of other aspects of the component such as a material composition thereof, intended manufacturing processes and parameters thereof, etc. The producibility prediction module 210 processes the component model data 220 and analyzes the geometry of the component and, optionally, other aspects of the component indicated by the component model data 220 to determine a producibility of the component. Various factors may be considered to determine producibility such as, but not limited to, a geometry of the component, a material composition of the component, a manufacturing process intended to be used to produce the component, a complexity of the manufacturing steps, etc. In some examples, the producibility prediction module 210 may further determine an estimated cost of manufacturing the component based on, for example, the producibility of the component.

The producibility prediction module 210 generates producibility prediction data 222 that includes various data indicating the determined producibility of the component. In some examples, the determined producibility may be represented based on a rating scale. For example, the producibility of the component may be rated on an alphanumeric scale (e.g., one to ten, A to D, zero to 100 percent, etc.), color-based scale (e.g., red-yellow-green), etc. In some examples, the determined producibility may be represented as a relative ranking, that is, as being more or less producible relative to another component design or model. In some examples, the producibility prediction data 222 may indicate specific aspects of the component that reduce the producibility of the component. For example, the producibility prediction data 222 may identify specific portions of the structure of the component that would be difficult to manufacture, such as a thin wall, a tight radius, a tight tolerance, small internal features, etc. In some examples, the producibility prediction data 222 may include an estimated cost of producing the component. The estimated cost may be determined based on, for example, the determined producibility of the component. In some examples, the estimated cost may be represented by an actual value or range of a currency. In some examples, the estimated cost may be represented based on a rating scale such as an alphanumeric scale (e.g., one to ten, A to D, etc.), color-based scale (e.g., red-yellow-green), etc.

In various embodiments, the generative design module 212 receives as input the producibility prediction data 222 generated by the producibility prediction module 210. The generative design module 212 processes the producibility prediction data 222 and determines one or more modifications to the component intended to improve the producibility of the component and/or reduce costs associated therewith. As a specific example, the producibility prediction data 222 may indicate that a specific wall of the component is too thin, and the generative design module 212 may determine that the wall may be thicker to improve the producibility of the component. In some examples, the modifications to the component may be limited to modifications that have little to no change to the performance and/or function of the component. In some examples, the modifications to the component may be limited based on one or more thresholds for acceptable change to the performance, function, and/or cost of the component (e.g., less than or equal to five percent increase to cost).

The generative design module 212 generates modification data 224 that includes various data indicative of the one or more modifications to the component. In some examples, the modification data 224 may include a 3D commented component model of the component that identifies the specific aspects of the component that were determined to reduce the producibility of the component and the corresponding modifications for such aspects of the component. For example, the 3D commented component model may include one or more aspects of the represented component highlighted, flagged, or otherwise marked, and recommended modifications may be referenced or provided for each of the marked aspects. In some examples, the recommended modifications may be observed by a user in response to interaction with the marked aspects of the component in the 3D commented component model. For example, a specific structural component (e.g., a wall) may be highlighted to indicate that a modification is recommended therefor, and a user may select the highlighted component to view the recommended modification.

In some examples, the modification data 224 may include a 3D modified component model of the component wherein one or more aspects of the component that were previously determined to reduce the producibility of the component are autonomously modified by the generative design module 212 to promote producibility of the component. For example, the 3D modified component model may include changes to structural or geometric aspects of the component, changes to a material composition of the component, changes to a manufacturing process intended to be used to produce the component, etc. In the example discussed previously wherein a specific wall of the component is determined to be too thin, the 3D modified component model may include changes to the structure of the represented component such that the wall has a larger thickness dimension and, optionally, adjustments to other portions of the structure to accommodate the change in thickness of the wall. In some examples, the 3D modified component model may indicate which aspects of the component have been changed relative to the original 3D component model provided in the component model data 220. Although not represented in FIG. 2, in some examples, the generative design module 212 may provide the modification data 224 to the producibility prediction module 210, and the producibility prediction module 210 may determine an updated producibility and/or cost of the component in view of the one or more modifications indicated in the modification data 224 or an updated producibility and/or cost of the component as represented in the 3D modified component model. In some examples, the generative design module 212 may transmit the modification data 224 to the CAD software. In some examples, the generative design module 212 may transmit the 3D modified component model to a casting system (e.g., the casting system 101) to produce the component using a casting process based on the 3D modified component model.

In some examples, the producibility prediction module 210 and/or the generative design module 212 may be integrated into a CAD software and operable therein. For example, a user may create a 3D component model in the CAD software, and then run the producibility prediction module 210 and/or the generative design module 212 within the CAD software to receive producibility information, modification recommendations, automated changes to the 3D component model, and/or production cost information.

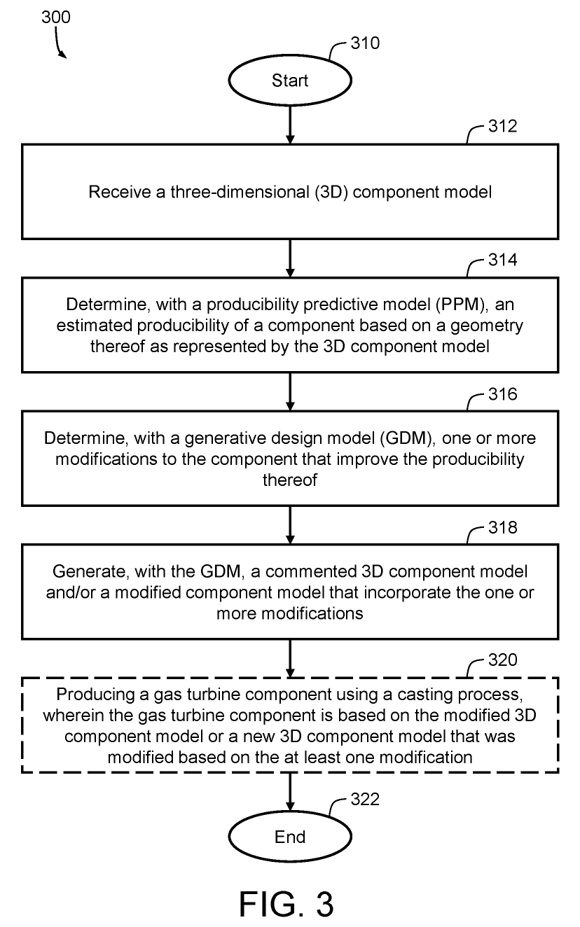

The systems disclosed herein, including the system 100, provide for methods of assisting in the design and production of articles. For example, FIG. 3 is a flowchart illustrating an exemplary method 300 for assisting in production of a cast component, such as a gas turbine engine component. The method 300 may start at 310.

At 312, the method 300 may include receiving a three-dimensional (3D) component model. At 314, the method 300 may include determining, with a producibility predictive model (PPM), an estimated producibility of the component based on a geometry thereof as represented in the 3D component model. At 316, the method 300 may include determining, with a generative design model (GDM), at least one modification to the component that improves the producibility thereof. At 318, the method 300 may include generating, with the GDM, a commented 3D component model and/or a modified component model that incorporates the modification. For example, the commented 3D component model may be representative of the component with one or more aspects thereof marked with a reference to the modification. The modified 3D component model may be representative of a modified version of the component wherein one or more aspects of the component has been changed based on the modification.

At 320, the method 300 may optionally include producing a gas turbine component using a casting process. The gas turbine component may be based on the modified 3D component model or a new 3D component model that was modified based on the at least one modification. For example, the modified 3D component model or the new 3D component model may be provided to a casting system (e.g., the casting system 101) to produce the component represented therein. The method 300 may end at 322.

In various examples, the PPM and/or the GDM may be implemented using one or more 3D-aware machine learning models, rather than a ruled-based algorithm. The 3D-aware machine learning models may be configured to understand, analyze, and manipulate geometric data (e.g., spatial structures such as point clouds, meshes, etc.) rather than, for example, language-based information. In some examples, the 3D-aware machine learning models may be trained with datasets for image processing (e.g., feature extraction, segmentation, classification, 3D model generation, etc.).

In some examples, the PPM and/or the GDM of the method 300 (and/or the producibility prediction module 210 and/or the generative design module 212 of the system 100) may be or include one or more neural network models, such as a feedforward neural network model, such as a multilayer perception model (MLP) that includes multiple layers of neurons (nodes). In some examples, the PPM and/or GDM may be or include one or more convolutional neural network (CNN) models that use convolutional layers to detect patterns like edges and textures, recurrent neural networks (RNN) models that use sequential data where past information influences current predictions, transformer models configured for 3D model understanding (e.g., vision transformers), generative adversarial network (GAN) models that are configured to generate new data, such as 3D models, and/or attention models that is configured to promote the neural network model’s ability to dynamically focus on objects of interest or priority.

In various examples, the PPM of the method 300 (and/or the producibility prediction module 210 of the system 100) may include one or more machine learning models that are trained with a dataset of 3D component designs and/or models and associated production thresholds and/or producibility parameters (and optionally cost thresholds and/or parameters). In various examples, the GDM of the method 300 (and/or the generative design module 212 of the system 100) may include one or more machine learning models that are trained with a dataset of 3D component designs or models (e.g., sample component models or drawings), wherein the GDM is configured to sample components from the dataset of component designs to generate modifications to an original 3D component model and/or generate a new 3D component model based on one or more original input 3D component models.

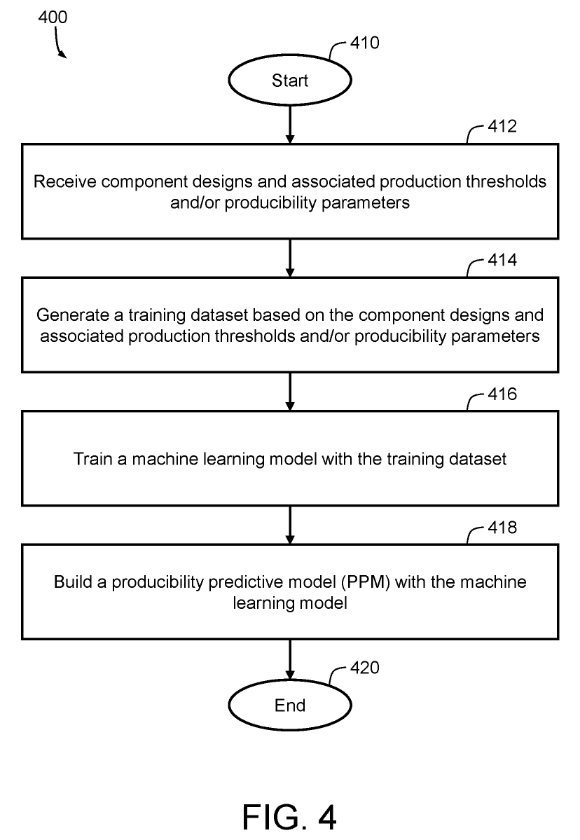

The systems disclosed herein, including the system 100, provide for methods of training and/or producing models configured to assist in the design and production of articles. For example, FIG. 4 is a flowchart illustrating an exemplary method 400 for training and/or producing models for assisting in production of a cast component, such as a gas turbine engine component. The method 400 may start at 410.

At 412, the method 400 may include receiving a plurality of component designs or models (e.g., a plurality of 3D component models produced with a CAD software) and associated production thresholds and/or producibility parameters, and optionally production cost thresholds and/or producibility-related cost parameters.

At 414, the method 400 may include generating a training dataset based on the component designs or models and associated production thresholds and/or producibility parameters. In some examples, data preparation for the training dataset may include various data preprocessing such as normalize coordinates (e.g., scale point clouds to a unit sphere), denoise and remove outliers, downsample for efficiency while retaining shape integrity. In some examples, data preparation for the training dataset may include data augmentation such as random rotations, translations, and scaling to improve model generalization.

At 416, the method 400 may include training a machine learning model with the training dataset. The machine learning model may include, for example, point cloud, voxel-based, mesh-based, or implicit representation models. The training of the machine learning model may include, for example, forward propagation where input data passes through the network generating predictions, loss calculation where the error between predictions and true outputs is measured using a loss function, backpropagation where gradients of the loss function with respect to weights are calculated and used to update the weights via an optimization algorithm (e.g., stochastic gradient descent), and/or iteration where the overall process repeats over many epochs until the model achieves satisfactory performance.

At 418, the method 400 may include building a functional model such as a producibility predictive model (PPM) and/or a generative design model (GDM) with the trained machine learning model. For example, the functional model may be configured to preprocess new 3D inputs and pass them through the trained machine learning model, perform postprocessing to refine predictions, and perform model optimization to quantize the model for faster inference.

The method 400 may end at 422.

The systems and methods disclosed herein provide various benefits over certain existing systems and methods. For example, the systems and methods disclosed herein provide for producibility estimation and design generation, thereby providing design engineers with actionable data during component design and potentially reducing design obstacles identified later in the production process that may extend the development lifecycle and lead time to fabrication.

Those of skill in the art will appreciate that the various illustrative logical blocks, modules, circuits, and algorithm steps described in connection with the embodiments disclosed herein may be implemented as electronic hardware, computer software, or combinations of both. Some of the embodiments and implementations are described above in terms of functional and/or logical block components (or modules) and various processing steps. However, it should be appreciated that such block components (or modules) may be realized by any number of hardware, software, and/or firmware components configured to perform the specified functions. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. For example, an embodiment of a system or a component may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments described herein are merely exemplary implementations.

Techniques and technologies may be described herein in terms of functional and/or logical block components, and with reference to symbolic representations of operations, processing tasks, and functions that may be performed by various computing components or devices. Such operations, tasks, and functions are sometimes referred to as being computer-executed, computerized, software-implemented, or computer-implemented. In practice, one or more processor devices can carry out the described operations, tasks, and functions by manipulating electrical signals representing data bits at memory locations in the system memory, as well as other processing of signals. The memory locations where data bits are maintained are physical locations that have particular electrical, magnetic, optical, or organic properties corresponding to the data bits. It should be appreciated that the various block components shown in the figures may be realized by any number of hardware, software, and/or firmware components configured to perform the specified functions. For example, an embodiment of a system or a component may employ various integrated circuit components, e.g., memory elements, digital signal processing elements, logic elements, look-up tables, or the like, which may carry out a variety of functions under the control of one or more microprocessors or other control devices.

When implemented in software or firmware, various elements of the systems described herein are essentially the code segments or instructions that perform the various tasks. The program or code segments can be stored in a processor-readable medium or transmitted by a computer data signal embodied in a carrier wave over a transmission medium or communication path. The “computer-readable medium”, “processor-readable medium”, or “machine-readable medium” may include any medium that can store or transfer information. Examples of the processor-readable medium include an electronic circuit, a semiconductor memory device, a ROM, a flash memory, an erasable ROM (EROM), a floppy diskette, a CD-ROM, an optical disk, a hard disk, a fiber optic medium, a radio frequency (RF) link, or the like. The computer data signal may include any signal that can propagate over a transmission medium such as electronic network channels, optical fibers, air, electromagnetic paths, or RF links. The code segments may be downloaded via computer networks such as the Internet, an intranet, a LAN, or the like.

Some of the functional units described in this specification have been referred to as “modules” in order to more particularly emphasize their implementation independence. For example, functionality referred to herein as a module may be implemented wholly, or partially, as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like. Modules may also be implemented in software for execution by various types of processors. An identified module of executable code may, for instance, comprise one or more physical or logical modules of computer instructions that may, for instance, be organized as an object, procedure, or function. Nevertheless, the executables of an identified module need not be physically located together, but may comprise disparate instructions stored in different locations that, when joined logically together, comprise the module and achieve the stated purpose for the module. Indeed, a module of executable code may be a single instruction, or many instructions, and may even be distributed over several different code segments, among different programs, and across several memory devices. Similarly, operational data may be embodied in any suitable form and organized within any suitable type of data structure. The operational data may be collected as a single data set, or may be distributed over different locations including over different storage devices, and may exist, at least partially, merely as electronic signals on a system or network.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language. The sequence of the text in any of the claims does not imply that process steps must be performed in a temporal or logical order according to such sequence unless it is specifically defined by the language of the claim. The process steps may be interchanged in any order without departing from the scope of the invention as long as such an interchange does not contradict the claim language and is not logically nonsensical.

Furthermore, depending on the context, words such as “connect” or “coupled to” used in describing a relationship between different elements do not imply that a direct physical connection must be made between these elements. For example, two elements may be connected to each other physically, electronically, logically, or in any other manner, through one or more additional elements.

As used herein, the term “substantially” denotes within 5% to account for manufacturing tolerances. Also, as used herein, the term “about” denotes within 5% to account for manufacturing tolerances.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A method, comprising:
receiving a computer-generated three-dimensional (3D) component model representative of a component to be produced;
determining, with a producibility predictive model (PPM), an estimated producibility of the component based on at least a geometry thereof as represented in the 3D component model, wherein the estimated producibility is indicative of a difficultly of manufacturing the component;
determining, with a generative design model (GDM), at least one modification to the component configured to improve the producibility of the component; and
generating, with the GDM:
a commented 3D component model representative of the component with one or more aspects thereof marked with a reference to the at least one modification, and/or
a modified 3D component model representative of a modified version of the component wherein one or more aspects of the component has been changed based on the at least one modification.

2. The method of claim 1, wherein determining the estimated producibility of the component is based on, in addition to the geometry, a material composition of the component, and parameters of an intended manufacturing method for producing the component.

3. The method of claim 1, further comprising:
determining, with the producibility predictive model (PPM), an estimated production cost of the component based on at least the geometry of the component as represented in 3D component model; and
providing the estimated production cost to the GDM for inclusion in the commented 3D component model or the modified 3D component model.

4. The method of claim 1, wherein the PPM and the GDM include 3D-aware machine learning models.

5. The method of claim 1, wherein the PPM and the GDM include neural network models.

6. The method of claim 1, wherein the PPM includes a 3D-aware machine learning model, and the method includes training the 3D-aware machine learning model with a dataset of 3D component models and associated production thresholds and/or producibility parameters.

7. The method of claim 1, wherein the GDM includes a 3D-aware machine learning model, and the method includes training the 3D-aware machine learning model on a dataset of 3D component models, wherein the GDM is configured to sample components from the dataset of 3D component models to determine the at least one modification and generate the commented 3D component model and/or the modified 3D component model.

8. The method of claim 1, further comprising providing the at least one modification, the commented 3D component model, and/or the modified 3D comment model to a computer aided design (CAD) software.

9. The method of claim 1, further comprising producing a gas turbine component using a casting process, wherein the gas turbine component is based on the modified 3D component model or a new 3D component model that was modified based on the at least one modification.

10. A system, comprising:
a producibility predictive model (PPM) executable on one or more processors of the system, wherein the PPM is configured to:
receive a computer-generated three-dimensional (3D) component model representative of a component to be produced; and
determine an estimated producibility of the component based on at least a geometry thereof as represented in the 3D component model, wherein the estimated producibility is indicative of a difficultly of manufacturing the component;
a generative design model (GDM) executable on the one or more processors of the system, wherein the GDM is configured to:
determine at least one modification to the component configured to improve the producibility of the component; and
generate:
a commented 3D component model representative of the component with one or more aspects thereof marked with a reference to the at least one modification, and/or
a modified 3D component model representative of a modified version of the component wherein one or more aspects of the component has been changed based on the at least one modification.

11. The system of claim 10, wherein the PPM is configured to determine the estimated producibility of the component based on, in addition to the geometry, a material composition of the component, and parameters of an intended manufacturing method for producing the component.

12. The system of claim 10, wherein the PPM is configured to:
determine an estimated production cost of the component based on at least the geometry of the component as represented in 3D component model; and
provide the estimated production cost to the GDM for inclusion in the commented 3D component model or the modified 3D component model.

13. The system of claim 10, wherein the PPM and the GDM include 3D-aware machine learning models.

14. The system of claim 10, wherein the PPM and the GDM include neural network models.

15. The system of claim 10, wherein the PPM includes a 3D-aware machine learning model trained with a dataset of 3D component models and associated production thresholds and/or producibility parameters.

16. The system of claim 10, wherein the GDM includes a 3D-aware machine learning model trained on a dataset of 3D component models, wherein the GDM is configured to sample components from the dataset of 3D component models to determine the at least one modification and generate the commented 3D component model and/or the modified 3D component model.

17. The system of claim 10, wherein the GDM is configured to provide the at least one modification, the commented 3D component model, and/or the modified 3D comment model to a computer aided design (CAD) software.

18. The system of claim 10, wherein the component is a gas turbine component configured to be installed in a gas turbine engine, wherein the component is intended to be produced with a casting process.

19. A system, comprising:
a producibility predictive model (PPM) executable on one or more processors of the system, wherein the PPM is configured to:
receive a computer-generated three-dimensional (3D) component model representative of a gas turbine component configured to be produced with a casting process and installed in a gas turbine; and
determine an estimated producibility of the component based on at least a geometry thereof as represented in the 3D component model, wherein the estimated producibility is indicative of a difficultly of manufacturing the component;
a generative design model (GDM) executable on the one or more processors of the system, wherein the GDM is configured to:
determine at least one modification to the component configured to improve the producibility of the component; and
generate:
a commented 3D component model representative of the component with one or more aspects thereof marked with a reference to the at least one modification, and/or
a modified 3D component model representative of a modified version of the component wherein one or more aspects of the component has been changed based on the at least one modification,
wherein the PPM includes a first 3D-aware machine learning model trained with a dataset of 3D component models and associated production thresholds and/or producibility parameters,
wherein the GDM includes a second 3D-aware machine learning model trained on the dataset of 3D component models, wherein the GDM is configured to sample components from the dataset of 3D component models to determine the at least one modification and generate the commented 3D component model and/or the modified 3D component model.

20. The system of claim 19, wherein the PPM is configured to:
receive the commented 3D component model or the modified 3D component model from the GDM; and
determine an updated estimated producibility of the component based on at least a geometry thereof as represented in the commented 3D component model or the modified 3D component model, wherein the updated estimated producibility is indicative of a difficultly of manufacturing the component with the one or more modifications.
